(19) United States
(12) Patent Application Publication
(10) Pub. No.: US 2015/0214078 A1
(43) Pub. Date: Jul. 30, 2015

(54) LOAD PORT APPARATUS

(71) Applicant: TDK Corporation, Tokyo (JP)

(72) Inventors: Tadamasa IWAMOTO, Tokyo (JP); Jun EMOTO, Tokyo (JP)

(73) Assignee: TDK Corporation, Tokyo (JP)

(21) Appl. No.: 14/605,553

(22) Filed: Jan. 26, 2015

(30) Foreign Application Priority Data
Jan. 29, 2014 (JP) 2014-014069

(51) Int. Cl. H01L 21/67; H01L 21/677; H01L 21/673

(52) U.S. Cl. CPC H01L 21/67017; H01L 21/67346; H01L 21/67353; H01L 21/67393; H01L 21/67772

(57) ABSTRACT

To prevent an increase with the passage of time in partial pressure of oxidizing gas in a FOUP, which is fixed to a FIMS system in an open state, a gas feed port is arranged on a lower surface of the FOUP so as to feed nitrogen to an inside of the FOUP through the gas feed port in a state where the FOUP is mounted on the FIMS system, in addition to nitrogen purge from an opening of the FOUP. A nitrogen feed system, which feeds nitrogen in a state where the FOUP is mounted on the FIMS system, is controlled so as to feed nitrogen at a low flow rate and a low pressure capable of suppressing the stirring-up of dust, which has a size that may cause a problem in wiring to be formed on a wafer, from the gas feed port and the like.

### BACKGROUND OF THE INVENTION

1. Field of the Invention

The present invention relates to a so-called Front-Opening Interface Mechanical Standard (FINS) system to be used between semiconductor processing apparatus. The FINS system opens and closes a lid of a so-called Front-Opening Unified Pod (FOUP) serving as a sealed container configured to contain a wafer, to thereby transfer the wafer to and from the pod. Further, the present invention relates to a load port apparatus, which is to be used in the FINS system, including a purge mechanism configured to clean an inside of the pod.

2. Description of the Related Art

A pod includes a body part configured to contain a wafer and a lid configured to close an opening of the body part. Further, the opening and closing operation of the lid and the insertion and removal of the wafer to and from the pod are performed through a mini-environment that is to accommodate a transportation robot provided in association with a semiconductor processing apparatus. A load port apparatus includes a wall configured to define the mini-environment, including an opening portion that communicates to the mini-environment, a pod mount base, which causes the opening of the pod to be opposed to the opening portion of the wall, and a door part configured to open and close the opening portion.

In this case, in general, an inside of the pod containing the wafer or the like is filled with dry nitrogen and the like controlled to be highly clean, to thereby prevent a contaminant, oxidizing gas, and the like from entering the inside of the pod. However, when the wafer in the pod is transferred into various processing apparatus so as to be subjected to predetermined processing, the inside of the pod and an inside of the processing apparatus constantly keep communicating to each other. A transportation apparatus configured to insert and remove the wafer to and from the inside of the pod is arranged in the mini-environment. A fan and a filter are arranged in the mini-environment, and in general, cleaned air containing particles and the like controlled to a certain cleanliness level is introduced into the inside of the mini-environment. However, when such air enters the inside of the pod, there is a risk in that oxygen or water in the air may adhere to a wafer surface. Further, oxygen and the like having entered the inside of the pod, which have not been considered as a significant problem in the related art, are currently drawing attention along with the downsizing and increase in performance of semiconductor devices.

The above-mentioned oxidizing gas forms an extremely thin oxide film on the wafer surface or various layers formed on the wafer. Due to such an oxide film, there is an emerging risk in that fine devices may not ensure desired characteristics. As countermeasures against this problem, there may be given a method of suppressing an increase in partial pressure of oxygen by introducing oxidizing gas having a controlled partial pressure of oxygen or the like into the inside of the pod. As a specific method, in Japanese Patent Application Laid-Open No. 2012-019046, there is a disclosure of a configuration in which inert gas such as nitrogen is fed to a space in front of the opening of the pod when the lid of the pod is opened and closed. In this configuration, the lid of the pod is removed so as to open the opening thereof, and the space in front of the opening of the pod is filled with inert gas fed from a gas feed nozzle, to thereby reduce the concentration of oxygen in the pod.

In the configuration disclosed in Japanese Patent Application Laid-Open No. 2012-019046, a chamber arranged in the space in front of the opening of the pod inside the load port partitions the space from the mini-environment, and the inside of the pod and the space partitioned from the mini-environment by the chamber are purged with inert gas. In this configuration, the partial pressure of oxygen in the space in front of the opening of the pod at a time of opening of the lid or the partial pressure of oxygen in the pod at a time of closing of the lid can be reduced.

In this case, during actual processing of a semiconductor wafer, it is necessary that the opening of the pod and the inside of the mini-environment communicate to each other so as to form a path through which the semiconductor wafer is inserted and removed space. Therefore, in the case where all the wafers in the pod are continuously subjected to processing and the like, the chamber is inevitably caused to keep a retracted state, thereby trading off the reduction in partial pressure of oxygen and the like in the pod to some degree. However, due to the thinning and the like of wiring in semiconductor devices in recent years, there is an increasing demand for further reducing a partial pressure of oxygen so as to suppress oxidation in the thinned wiring also in a state where the lid is opened during continuous processing, which has not been considered as a problem hitherto.

### SUMMARY OF THE INVENTION

The present invention has been made in view of the above-mentioned circumstances, and it is an object of the present invention to provide a load port apparatus capable of suppressing a partial pressure of oxidizing gas such as oxygen in a pod to a predetermined low level even during continuous processing of wafers.

In order to achieve the above-mentioned object, according to one embodiment of the present invention, there is provided a load port apparatus capable of inserting and removing an object to be contained to and from a pod by removing a lid from the pod so as to open an opening of the pod; the pod being capable of containing the object to be contained and forming a sealed space by closing the opening with the lid; the pod including at least one pod-side gas feed port, which is formed on a wall surface of the pod and capable of feeding gas from an outside to an inside of the pod; the load port apparatus including: a mount base configured to allow the pod to be mounted thereon; a mini-environment configured to accommodate a mechanism for transporting the object to be contained, the mini-environment being arranged adjacently to the mount base; an opening portion formed in a wall, which is arranged adjacently to the mount base so as to define a part of the mini-environment, the opening portion being arranged so as to be opposed to the opening of the pod mounted on the mount base; a door configured to cause the inside of the pod and the mini-environment to communicate to each other by opening the opening portion while holding the lid, the door being capable of closing the opening portion while holding the lid; a feed port configured to feed predetermined gas to the inside of the pod in cooperation with the at least one pod-side gas feed port; a purge nozzle configured to feed the predetermined gas toward the inside of the pod with the lid opened, the purge nozzle being arranged corresponding to a lateral side of the opening portion on the mini-environment side; and a control unit configured to determine a period of time for simultaneously feeding the predetermined gas from the purge nozzle and the feed port to the inside of the pod in a state where the lid is removed from the pod by the door.

Note that, in the above-mentioned load port apparatus, it is preferred that the at least one pod-side gas feed port be arranged at a position where the at least one pod-side gas feed port is capable of forming a gas discharge path leading to the outside of the pod along an opposing surface of the opening of the pod for the predetermined gas fed from the purge nozzle to the inside of the pod. Further, it is preferred that the control unit include: an opening and closing detection unit configured to detect opening and closing of the opening, which are performed by the door through use of the lid; and a unit configured to start feed of the predetermined gas from the purge nozzle in accordance with the opening of the opening, which is detected by the opening and closing detection unit.

Further, in the load port apparatus, it is preferred that the purge nozzle form a gas flow parallel to a flat mount surface of the mount base. In addition, it is preferred that the purge nozzle form a gas flow including a laminar flow, which is parallel to an extending plane of the object to be contained having a plate shape. Further, it is preferred that the pod include at least one discharge port, which is formed on the wall surface of the pod and capable of discharging gas to the outside, and that the load port apparatus further include a discharge valve configured to discharge the gas from the inside of the pod in cooperation with the at least one discharge port. Alternatively, it is preferred that the load port apparatus further include: an enclosure being arranged in the mini-environment so as to be continuous from the opening portion and covering a movement space of the door, the enclosure including a second opening portion configured to enable the mechanism for transporting the object to be contained to pass through the second opening portion together with the object to be contained while causing the opening portion and the mini-environment to communicate to each other; and a curtain nozzle configured to form a downflow parallel to the opening portion in the enclosure, the curtain nozzle and the purge nozzle being arranged in the enclosure.

Further, in order to achieve the above-mentioned object, according to one embodiment of the present invention, there is provided a control method for a load port apparatus capable of inserting and removing an object to be contained to and from a pod by removing a lid from the pod so as to open an opening of the pod; the pod being capable of containing the object to be contained and forming a sealed space by closing the opening with the lid; the pod including at least one pod-side gas feed port, which is formed on a wall surface of the pod and capable of feeding gas from an outside to an inside of the pod; the control method including: mounting the pod on a mount base of the load port apparatus; removing the lid from the pod so that a mini-environment and the inside of the pod communicate to each other through the opening; feeding predetermined gas from the at least one pod-side gas feed port to the inside of the pod; feeding the predetermined gas from a purge nozzle arranged in the mini-environment to the inside of the pod; and closing the opening with the lid; the feeding the predetermined gas from the purge nozzle to the inside of the pod and the feeding the predetermined gas from the at least one pod-side gas feed port to the inside of the pod being performed simultaneously with each other at least during a period in which the opening is in an opened state.

According to one embodiment of the present invention, even when the lid is opened and the inside of the pod and the mini-environment communicate to each other, high-purity inert gas and the like are fed directly to the inside of the pod. Therefore, even during continuous processing of the wafers, the partial pressure of oxidizing gas such as oxygen in the pod can be suppressed to a predetermined low level.

Further features of the present invention will become apparent from the following description of exemplary embodiments with reference to the attached drawings.

### BRIEF DESCRIPTION OF THE DRAWINGS

FIG. 1 is a schematic view illustrating a purge method in a load port apparatus of the present invention.

FIG. 2 is a perspective view illustrating a schematic configuration of a main portion of the load port apparatus according to one embodiment of the present invention.

FIG. 3 is a view illustrating a schematic configuration of a part of a load port, a pod, a lid for the pod, and an opener in a cross section perpendicular to a pod opening according to one embodiment of the present invention illustrated in FIG. 1.

FIG. 4 is a view illustrating a feed direction of purge gas to be fed from a purge nozzle toward an inside of the pod.

FIG. 5 is a schematic view of a first opening portion when viewed from a mini-environment side, for illustrating a gas feed state from the purge nozzle and a curtain nozzle illustrated in FIG. 2.

FIG. 6 is a view illustrating a mount base in the load port apparatus illustrated in FIG. 1 in a vertical cross section including a gas feed valve.

FIG. 7 is a view illustrating an example of a schematic configuration of an upper surface of the mount base of the present invention, when viewed from above.

FIG. 8 is a flowchart illustrating steps of performing a purge operation in the load port apparatus according to one embodiment of the present invention.

### DESCRIPTION OF THE EMBODIMENTS

Now, an embodiment of the present invention is described with reference to the drawings. Note that, the following embodiment below is not intended to limit the present invention as recited in the claims, and further all the combinations of features described in the embodiment are not necessarily required as the means for solving the problem of the present invention.

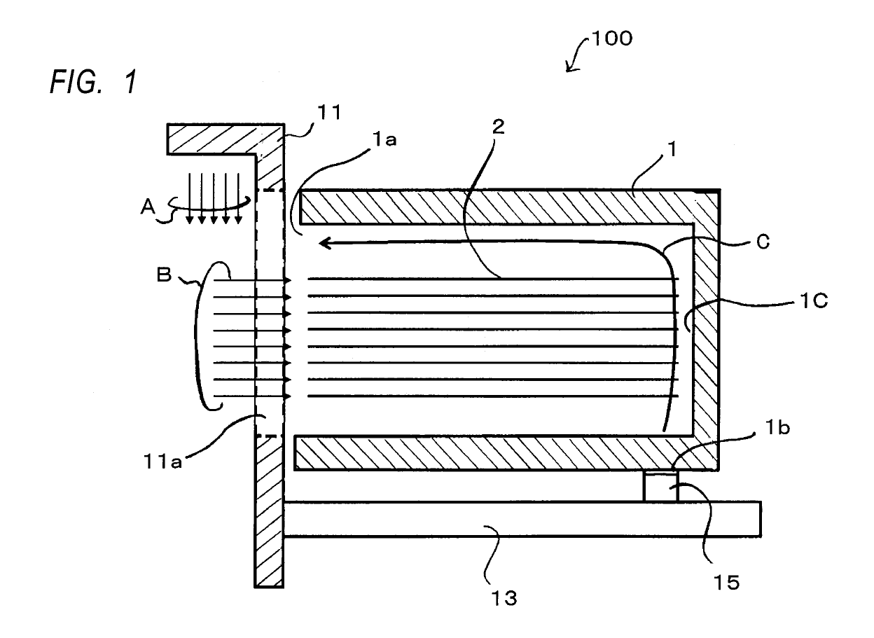

FIG. 1 is an explanatory view schematically illustrating a mode of a purge operation according to one embodiment of the present invention. FIG. 1 illustrates a cross section of a first opening portion, a pod, and an opening of the pod described later. Further, FIG. 1 schematically illustrates a feed mode of inert gas to be fed to the above-mentioned components by the arrows. Note that, the purge operation described later refers to an operation involving introducing inert gas such as nitrogen or predetermined gas into the inside of the pod so as to eliminate gas that has been present in the pod. In FIG. 1, wafers 2, which are objects to be contained, are contained in a pod 1 in a range of a predetermined holding region thereof so as to extend respectively in a horizontal direction and to be parallel to each other in a vertical direction. Note that, the horizontal direction and the vertical direction are matched with a direction in which a bottom surface of the pod 1 extends and a direction in which an opening plane of the pod 1 extends, respectively, and may be different from directions defined as a horizontal direction and a vertical direction in actuality.

In FIG. 1, a load port apparatus 100 according to the present invention includes a wall 11 configured to define a mini-environment and a mount base 13. In FIG. 1, a lid (not shown) of the pod 1 has already been opened so that an opening portion 11a formed in the wall 11 and the inside of the pod 1 communicate to each other. On the mount base 13, a bottom gas feed port 15 is arranged so as to be aligned with a pod-side gas feed port 1b, which is arranged on an opposing surface of the pod 1, and thus predetermined inert gas can be fed to the inside of the pod 1.

In the state of FIG. 1, in the present invention, the inert gas is fed so as to flow in three directions indicated by the arrows in FIG. 1. First, in the mini-environment (space positioned on a left side with respect to the wall 11 in FIG. 1), a first gas flow A, which is directed from above to below in FIG. 1 in parallel to the opening portion 11a, is formed. The first gas flow A forms an inert gas curtain that suppresses the diffusion of gas in the mini-environment from the opening portion 11a to the inside of the pod 1. Further, a second gas flow B, which is directed from the mini-environment to the inside of the pod 1 through the first opening portion 11a, is formed. The second gas flow B forms a main gas feed path that purges the inside of the pod 1 with the inert gas. In order to effectively purge also a space between the wafers 2, the inert gas is fed, as the second gas flow B, so as to flow along a direction in which the wafers 2 extend and to have main directivity from an opening 1a to an opening opposing surface 1c of the pod 1.

A third gas flow C is formed with the inert gas fed to the inside of the pod 1 through the pod-side gas feed port 1b described above. It is preferred that the pod-side gas feed port 1b be formed on an outer side with respect to an edge of the wafer 2 when viewed from a height direction. In this case, the inert gas fed from the pod-side gas feed port 1b does not directly interfere with the wafer 2. Therefore, the fed inert gas circulates easily, and the third gas flow C is formed easily with the inert gas. Further, it is preferred that the pod-side gas feed ports 1b be arranged at corners of the pod 1 in pairs symmetrically across a center axis of the pod 1 when viewed from the height direction. Through the arrangement of the pod-side gas feed port 1b to be paired with a purge nozzle 21 described later, the third gas flow C can be formed in a more suitable manner. Note that, although this arrangement is suitable, due to the configuration of the load port apparatus 100, there may be adopted such a configuration that a hole of the pod-side gas feed port 1b overlaps with the wafer 2 in the height direction when using the interaction between the second gas flow B and the third gas flow C. Further, as another exemplary embodiment, the pod-side gas feed port 1b is arranged on a wall surface of the pod 1 in the vicinity of the opening opposing surface 1c described above. With this arrangement, the third gas flow C directed from the bottom surface to an upper surface of the pod 1 along the opening opposing surface 1c is formed more reliably. The third gas flow C forces gas, which has reached the vicinity of the opening opposing surface 1c due to the second gas flow B, so as to flow upward, and further discharges the gas to an outer space along, for example, the upper surface of the pod 1 illustrated in FIG. 1, in which the second gas flow B is weak.

In the present invention, the inert gas is fed so as to form the three gas flows in a state where the wafer 2 is continuously inserted and removed and a lid 3 is opened. Thus, even in the case where a plurality of the wafers 2 in the pod 1 are subjected to continuous processing, the sufficient inert gas is fed to the entire region in the pod so that an increase in partial pressure of oxygen is uniformly suppressed. Note that, although the case where the pod-side gas feed port 1b is arranged in the vicinity of the opening opposing surface 1c is exemplified as the exemplary embodiment, the arrangement of the pod-side gas feed port 1b may be modified in accordance with an actual apparatus configuration.

Specifically, there is no limitation on the arrangement of the pod-side gas feed port 1b as long as the pod-side gas feed port 1b is arranged or configured so as to form the third gas flow C that is a gas flow reaching an outer space from the vicinity of a reaching point of the flow of the inert gas fed from substantially the entire region of the opening portion 11a by the second gas flow B described above. Note that, from the viewpoint of the uniform purge in the pod 1, it is preferred that the second gas flow B be formed in a range wider than a region in which the wafers 2 are held. Similarly, it is preferred that the second gas flow B be formed so as to include a laminar flow in parallel to a flat surface of the mount base 13 on which the pod 1 is mounted or in parallel to an extending plane of the wafer 2. Further, due to the addition of the first gas flow A, a decrease in purity of the inert gas fed to the inside of the pod 1 by the second gas flow B is suppressed. According to the present invention, at least the second gas flow B and the third gas flow C are used together in a state where the lid 3 of the pod 1 is opened, and hence an object of keeping a state of a low partial pressure of oxygen is achieved.

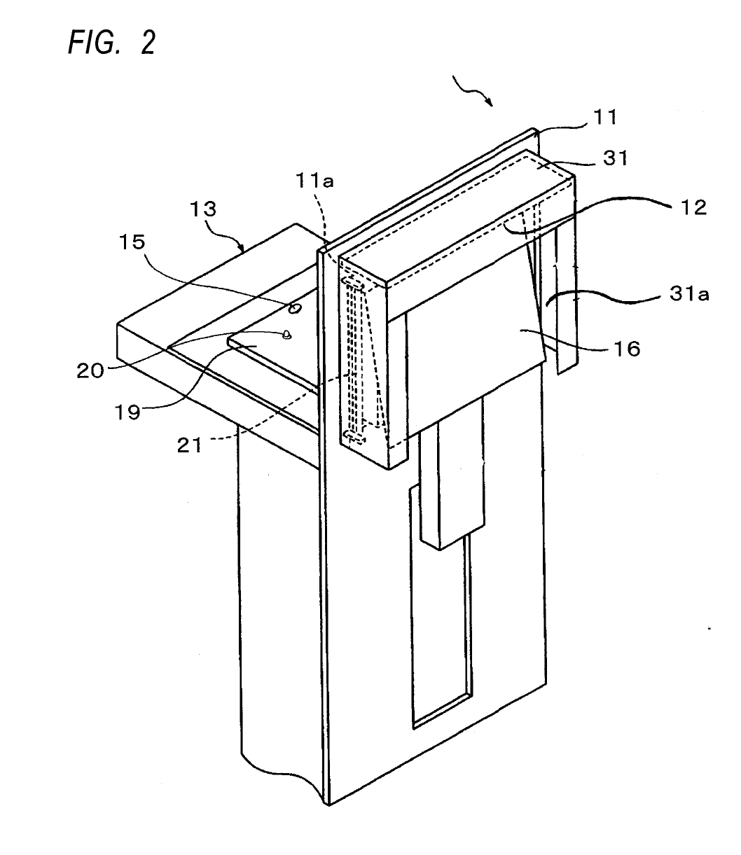

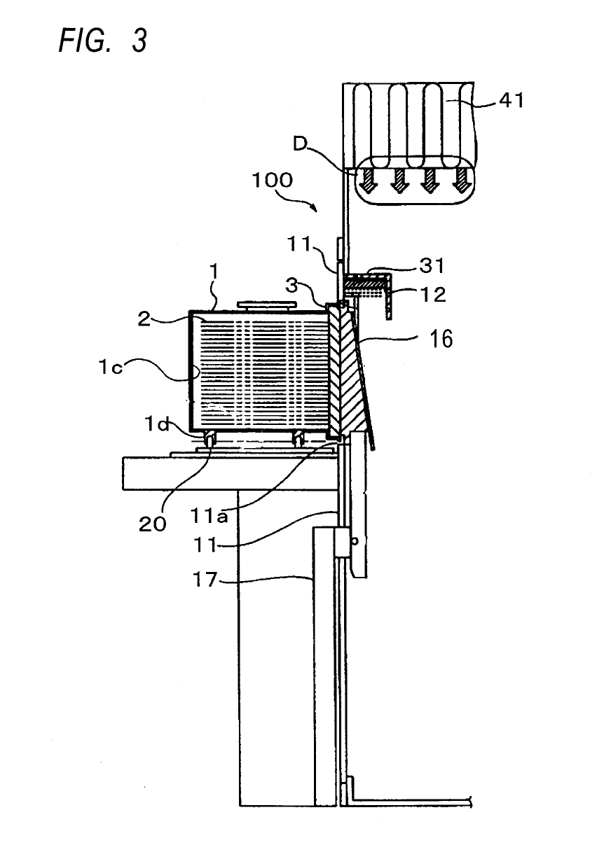

Next, a specific embodiment of the present invention is described with reference to the drawings. FIG. 2 is a perspective view illustrating a schematic configuration of a main portion of the load port apparatus 100 according to one embodiment of the present invention. Note that, the same components as those described above are denoted by the same reference symbols, and the detailed descriptions thereof are hereinafter omitted. FIG. 2 illustrates, as main components in the load port apparatus 100, the mount base 13, a door 16, a part of a door opening and closing mechanism 17, the wall 11 forming a part of the mini-environment in which the opening portion 11a is formed, and an enclosure 31. Further, FIG. 3 is a view illustrating, in cross section, a schematic configuration of the load port apparatus 100 and the pod 1 in a state where the pod 1 is mounted on the load port apparatus 100 (mount base 13) and the lid 3 of the pod 1 is held in abutment against the door 16.

The bottom gas feed port 15 described above, a movable plate 19, and a positioning pin 20 (see FIG. 3) are provided in association with the mount base 13. In actuality, the pod 1 is mounted on the movable plate 19. Further, the movable plate 19 is operable so as to bring the mounted pod 1 close to or away from the opening portion 11a and has a flat surface for mounting the pod 1 in an upper portion. The positioning pin 20 is embedded in the flat surface of the movable plate 19. When the positioning pin 20 is fitted in a positioning recess 1d formed in a lower surface of the pod 1, the positional relationship between the pod 1 and the movable plate 19 is determined uniquely. Further, as described above, when the pod 1 is mounted on the movable plate 19, the bottom gas feed port 15 and the pod-side gas feed port 1b communicate to each other so that the inert gas can be fed to the inside of the pod 1 through those ports.

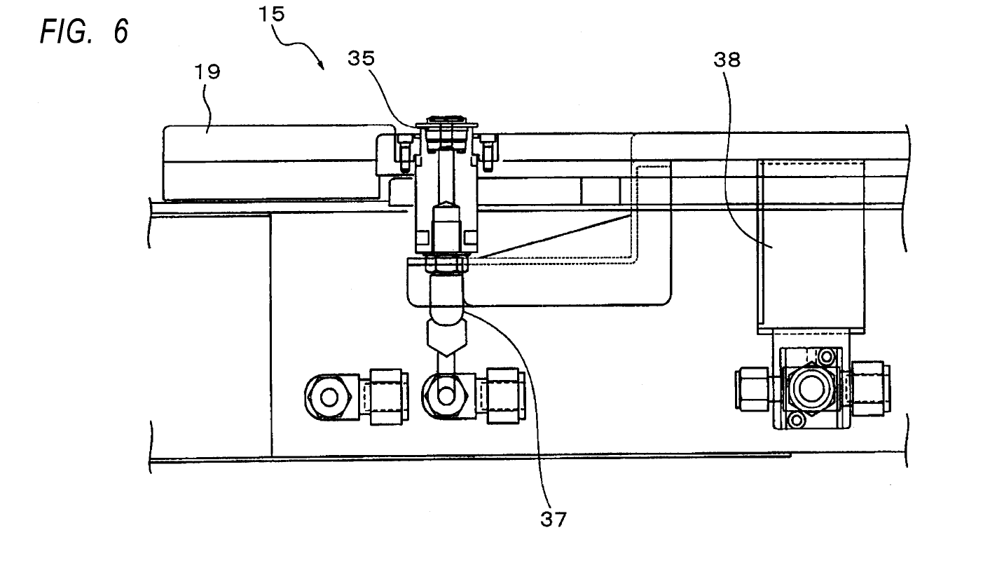

Now, the bottom gas feed port 15 is described with reference to FIG. 6 that illustrates the mount base 13 in a vertical cross section including the bottom gas feed port 15. The bottom gas feed port 15 includes a gas feed valve 35 formed of a check valve capable of feeding gas only in one direction. The inert gas is fed to the gas feed valve 35 through a gas feed pipe 37 by an inert gas feed system (not shown), which feeds the inert gas to the gas feed valve 35 while controlling a gas pressure and a flow rate or stops feeding the inert gas to the gas feed valve 35. Further, the gas feed valve 35 is fixed to the mount base 13 through intermediation of a valve raising and lowering mechanism 38. The valve raising and lowering mechanism 38 moves the gas feed valve 35 between a feed position at which the gas feed valve 35 can feed the inert gas to the pod 1 and a lower standby position at which the gas feed valve 35 does not feed the inert gas to the pod 1 while avoiding the contact with a bottom surface of the pod 1.

The opening portion 11a formed in the wall 11 has such a size that the lid 3 configured to close the opening 1a is fitted in the opening portion 11a when the pod 1 is brought closest to the opening portion 11a. That is, the opening portion 11a is formed into a rectangular shape slightly larger than a rectangular outer shape of the lid 3. Note that, it is appropriate that a position at which the movable plate 19 stops the pod 1 be located at a position where the door 16 allows the lid 3 of the pod 1 to be removed from a pod body. The door 16 is supported by the door opening and closing mechanism 17 through intermediation of a door arm. The door opening and closing mechanism 17 allows the door 16 to move between a position at which the door 16 substantially closes the opening portion 11a and a retracted position at which the door 16 completely opens the opening portion 11a and a transportation mechanism (not shown) can insert and remove the wafer 2 to and from the inside of the pod 1 through the opening portion 11a.

In this embodiment, the enclosure 31 configured to define a front space on the mini-environment side of the opening portion 11a is used. The enclosure 31 is formed of a baffle plate on an upper side and baffle plates on both lateral sides so as to have a rectangular parallelepiped shape with one surface opposed to the wall 11 being an open surface. A lateral length of a space formed in the enclosure 31 (length in a direction corresponding to a side of the opening portion 11a extending in a horizontal direction, that is, width) is set to be a length capable of accommodating the door 16 and a curtain nozzle 12 described later. Further, a vertical length (length in a direction corresponding to a side of the opening portion 11a extending in a vertical direction) is set to be a minimum length capable of accommodating the door 16 irrespective of whether the door 16 is located at the retracted position or at the position of closing the opening portion 11a. Note that, the baffle plates on both the lateral sides may be coupled to each other via a plate member for reinforcement interposed therebetween.

A second opening portion 31a is formed in a surface of the enclosure 31, which is opposed to the opening portion 11a. Although the second opening portion 31a is arranged so as to be opposed to the opening portion 11a, it is preferred that the size of a rectangle be set to such a minimum size that the enclosure 31 does not interfere with the operation of inserting and removing the wafer 2 to and from the inside of the pod 1 by the transportation mechanism (not shown), which is arranged in the mini-environment. Through the arrangement of the enclosure 31, the mutual diffusion of gas is suppressed between a downflow D formed of outside gas fed from an upper portion of the mini-environment by a fan filter unit 41 and the gas fed from the curtain nozzle 12 described later.

The curtain nozzle 12 is arranged in an uppermost portion in an inside of the enclosure 31 and in an upper portion of a space immediately in front of the opening portion 11a (upper portion of an upper side of the opening portion 11a) in the inside of the enclosure 31. The curtain nozzle 12 is arranged so as to form a downflow in the enclosure 31 and to form a gas curtain immediately in front of the opening portion 11a. In this embodiment, the curtain nozzle 12 is positioned on a lower surface of the baffle plate on the upper side of the enclosure 31 so as to form the first gas flow A illustrated in FIG. 1. Further, a region of the enclosure 31 in a direction in which the door 16 is retracted is opened so that the downflow formed of the inert gas in the enclosure 31 can be formed stably.

Further, the purge nozzle 21 configured to feed purge gas for purging the inside of the pod 1 is also arranged in the enclosure 31. The purge nozzle 21 includes a tubular purge nozzle body extending in one direction so as to be connected to a purge gas feed system (not shown). A pair of the purge nozzle bodies is arranged on a different side from the mount base 13 on which the pod 1 is mounted with respect to the opening portion 11a so as to extend in parallel to both lateral sides of the opening portion 11a adjacently to both the lateral sides on an outer side of the opening portion 11a.

For example, in the case where the inert gas is fed from a one-sided portion such as an upper portion of the pod 1 so as to purge the inside of the pod 1 with the inert gas, a gas accumulated region may be formed in a lower portion of the pod 1, in particular, in the vicinity of the opening portion 11a, with the result that it is difficult to purge the inside of the pod 1 efficiently. Alternatively, sufficient effects may not be obtained unless the inert gas keeps being excessively fed. When the purge nozzle 21 feeds the inert gas to a region in which the wafer 2 is contained or to a region wider than the region in which the wafer 2 is contained as in the present invention, such a gas accumulated region can be prevented from being formed. That is, the purge nozzles 21 are arranged corresponding to both the lateral sides of the opening portion 11a on the mini-environment side so as to feed the inert gas toward the inside of the pod 1 in the region wider than the region in which the wafer 2 is held.

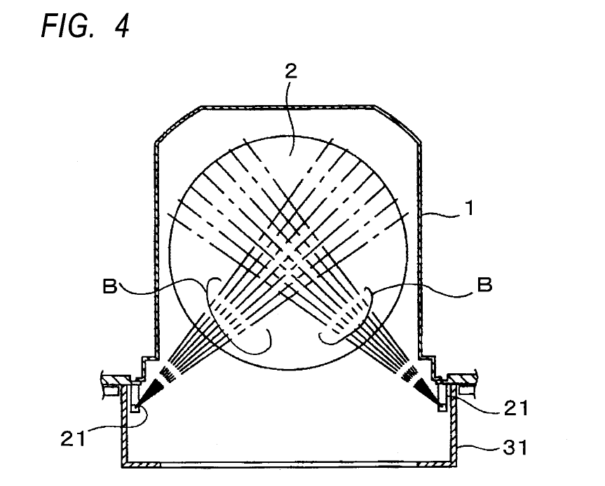

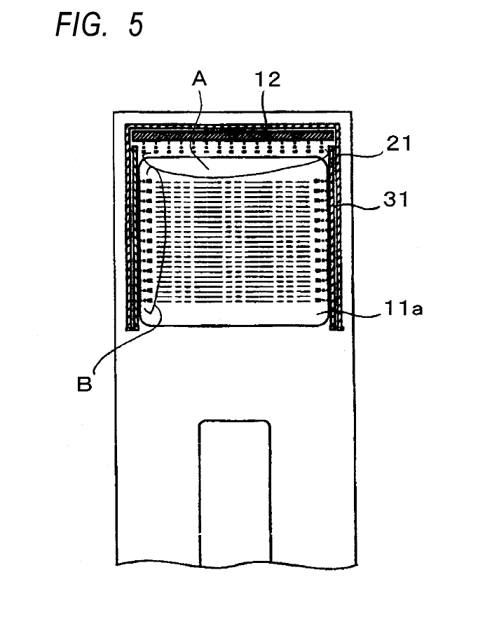

FIG. 4 illustrates a schematic configuration of the purge nozzles 21, the pod 1, the wafer 2, and the enclosure 31, when viewed from above, and FIG. 5 illustrates a schematic configuration of those components, when viewed from the mini-environment side. The purge nozzle 21 includes purge nozzle opening portions that correspond to a containing range of the wafer 2 in the pod 1 or a range lager than the containing range. Further, the purge nozzle opening portions are also formed so as to be directed to a center portion of the wafer 2 in the pod 1. That is, it is preferred that the main direction of the second gas flow B caused by the inert gas fed from the purge nozzle 21 be parallel to a plane extending perpendicularly to a feed direction of gas from the curtain nozzle 12 and be directed to a point located at an equal distance from both the purge nozzles 21 in the plane. Due to the combination of the two gas flows from both the purge nozzles 21, the second gas flow B directed from the opening 1a of the pod 1 to the opening opposing surface 1c can be formed in a wide range on the wafer 2.

For example, when a processed wafer contained in the pod 1 is removed from the pod 1, it is considered that there is a risk in that gas used during processing, which adheres to the surface of the wafer, may be desorbed from the surface of the wafer so as to contaminate the inside of the pod 1. In the present invention, the desorbed gas is eliminated from the vicinity of the surface of the wafer by the second gas flow B formed of the purge gas and is forced to flow toward the opening opposing surface 1c located at the back of the pod 1. The gas forced to flow toward the opening opposing surface 1c is further carried along the opening opposing surface 1c by the third gas flow C formed of bottom purge gas. Thus, the gas is discharged out of the pod 1 along a gas discharge path formed by those gas flows. Further, the gas discharged out of the pod 1 is carried to the mini-environment and further to the outer space from below the enclosure 31 by the first gas flow A serving as the gas curtain. Specifically, the inside of the pod 1 containing the processed wafer can be purged more efficiently by forming a plurality of gas flows simultaneously.

According to the present invention, even when the lid 3 of the pod 1 is opened, and hence outside gas may enter the inside of the pod 1, an increase in partial pressure of oxidizing gas can be suppressed by continuously feeding a relatively small amount of gas. For example, in the related art, even when the processing time of a single wafer is not long, it is required to wait for the completion of one processing while appropriately closing the lid 3 so as to suppress a partial pressure of oxygen. However, according to the present invention, even when the standby state continues for a long period of time, the partial pressure of oxidizing gas is constantly kept at a predetermined value or less. Thus, there is obtained an effect that the quality of all the wafers in the pod can be kept uniform. Further, each wafer can be continuously subjected to a processing step in a state where the lid 3 is left open, and hence there are also obtained effects that the processing time is shortened and the load on the apparatus is reduced.

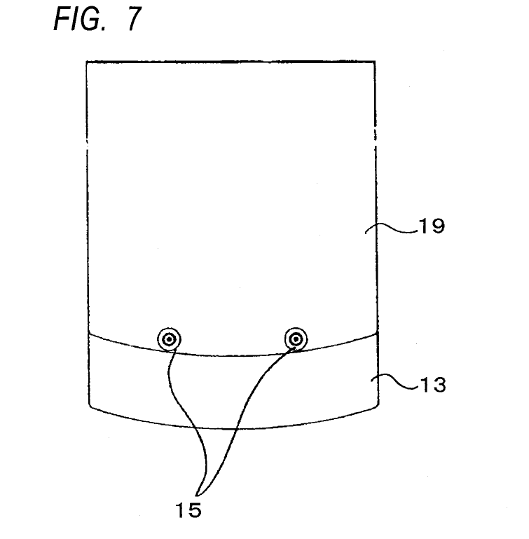

Note that, similarly to the bottom gas feed port 15, the gas feed path configured to feed the inert gas to each of the curtain nozzle 12 and the purge nozzle 21 is also connected to the inert gas feed system (not shown), which feeds the inert gas while controlling a gas pressure and a flow rate or stops feeding the inert gas. Thus, the flow rate of the inert gas fed from each nozzle and the like can be appropriately changed in accordance with the internal volume and inner shape of the pod 1, the number of wafers to be contained in the pod 1, the containing mode, and the like. Further, although the enclosure 31 is used in this embodiment, for example, there may be adopted such a shape that only the curtain nozzle 12 is covered so as to be shielded from the downflow D or such a shape covering the curtain nozzle 12 may be omitted. Further, it is preferred that the bottom gas feed port 15 be arranged so as to be close to the opening opposing surface 1c of the pod 1 as illustrated in FIG. 7 and be arranged in the vicinity of a region in which the second gas flow B impinges on the inner wall of the pod 1 as illustrated in FIG. 4. However, the arrangement of the bottom gas feed port 15 may not be particularly limited as long as the third gas flow C, which discharges the gas having passed between the respective wafers 2 to the outer space along the inner wall of the pod 1, can be formed. Further, in the exemplified embodiment, in order to form three kinds of suitable gas flows in the pod 1, the purge nozzles 21 are arranged on both the lateral sides of the opening portion 11a. However, if the above-mentioned three kinds of gas flows can be formed in a suitable manner so as to form a flow path leading from the inside of the pod 1 to the outside, the purge nozzle 21 may also be arranged on only one lateral side.

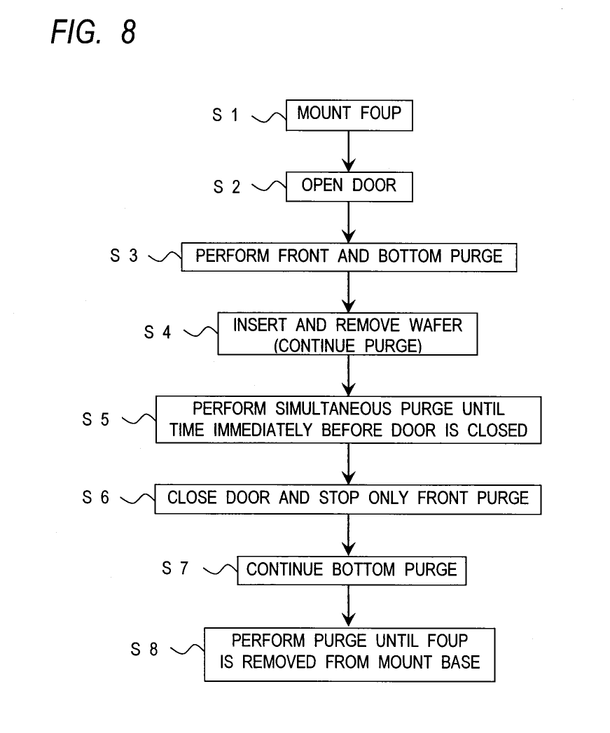

Next, the operation of the above-mentioned configuration when the wafer 2 is inserted and removed to and from the pod 1 in actuality is described. FIG. 8 is a flowchart illustrating the respective steps performed in the load port apparatus 100 in this case. First, in Step S1, the pod 1 is mounted on the mount base 13. At this time, the door 16 substantially closes the opening portion 11a. After the pod 1 is mounted on the mount base 13, the movable plate 19 moves toward the opening portion 11a and stops at a position where the lid 3 is brought into abutment against the door 16. The door 16 holds the lid 3 with an engagement mechanism (not shown) so as to remove the lid 3 from the pod 1 and is retracted downward from a front of the opening portion 11a in Step S2. In this case, the downflow D from the fan filter unit 41 and the gas curtain from the curtain nozzle 12 are constantly formed from the time before the pod 1 is mounted on the mount base 13.

After the completion of the retraction operation of the door 16 by the door opening and closing mechanism 17 in Step S2 or during the retraction operation, the inside of the pod 1 starts being purged with the inert gas fed from the purge nozzle 21 and the inert gas fed from the pod-side gas feed port 1b (Step S3). In this state, the opening 1a of the pod 1 is opened, and thus the wafer 2 can be transferred to the inside of the pod 1 through the second opening portion 31a of the enclosure 31 by the transportation mechanism (not shown) arranged in the mini-environment. While this state is kept, the operation of inserting and removing the wafers 2 in Step S4 and a variety of processing for the wafers 2 are performed.

In this state, the wafers 2 are continuously inserted and removed to and from the pod 1. During the transportation operation, the inside of the pod 1 is continuously purged so as to decrease a partial pressure of oxidizing gas in the pod 1 (Step S5). After the completion of the delivery operation of the wafers 2 to be contained in the pod 1, the lid 3 is closed in Step S6. Further, at this time, only the feed of the inert gas from the purge nozzle 21 is stopped, while the feed of the inert gas from the bottom gas feed port 15 is continued. This operation is performed by a control unit configured to control a system configured to feed the inert gas to the purge nozzle 21 and a system configured to feed the inert gas to the bottom gas feed port 15.

The control unit determines a period of time for simultaneously feeding the inert gas from the purge nozzle 21 and the bottom gas feed port 15 to the inside of the pod 1 in a state where the lid 3 is removed from the pod 1 by the door 16. Note that, the control unit includes an opening and closing detection unit configured to detect opening and closing of the opening 1a, which are performed by the door 16 through use of the lid 3, and a unit configured to stop the feed of the inert gas from the purge nozzle 21 in accordance with the closing of the opening 1a, which is detected by the opening and closing detection unit. Due to the arrangement of the opening and closing detection unit and the unit configured to stop the feed of the inert gas, compared to the case where time control is merely performed, the unnecessary feed of the inert gas is suppressed, and the gas usage amount and the stirring-up of dust and the like caused by the unnecessary feed of gas can be suppressed.

In this state, the feed of the inert gas to the inside of the pod 1 is kept for a predetermined period of time in Step S7. With this, the inside of the pod 1 has an internal pressure higher than the atmospheric pressure with the inert gas so as to achieve, for example, a state capable of suppressing the risk of the entry of the air from a seal and the like of the lid 3. Thereinafter, this state is kept continuously until the pod 1 is removed from the mount base 13 in Step S8. The above-mentioned simultaneous feed of the inert gas is performed by the control unit, and thus the second gas flow B and the third gas flow C are formed in a suitable manner in the pod 1 with the lid 3 opened, with the result that a uniform purge operation is performed over the entire region in the pod 1.

Note that, in the above-mentioned embodiment, such a configuration that only the bottom gas feed port 15 is arranged on the mount base 13 is exemplified. However, for example, in the case where the sealing ability of the lid 3 is degraded with the passage of time due to the excessive feed of the inert gas to the pod 1 in Step S7 and the like described above, the configuration may be appropriately modified in consideration of this case. Thus, the partial pressure of oxidizing gas may be decreased more effectively by discharging the gas from the inside of the pod 1, in which the internal pressure is increased by the feed of gas, so as to form a flow of clean gas in the pod 1. In this case, it is preferred that a gas discharge port be arranged in addition to the bottom gas feed port 15 arranged on an upper surface of the mount base 13. Respective valves of the gas discharge port have a structure in conformity to the structure illustrated in FIG. 6, and a port corresponding to each of the valves is arranged also on a bottom surface of the pod 1.

Note that, although this embodiment has been described with respect to the FOUP and the FIMS, the application examples of the present invention are not limited thereto. The lid opening and closing system according to the present invention can be applied to a container of a front-opening type configured to contain a plurality of objects to be contained and a system configured to insert and remove the objects to be contained to and from the container by opening and closing a lid of the container. Thus, the partial pressure of oxidizing atmosphere in the container can be kept low. Further, in the case of using, as gas to be filled in the container, specific gas having desired characteristics instead of the inert gas, the partial pressure of the specific gas in the container can also be kept high through use of the lid opening and closing system according to the present invention.

According to the present invention, the purge gas is fed toward the wafer, and the gas is fed from the bottom surface of the pod so as to form a circulation path of the fed gas in the pod. Thus, an increase in partial pressure of oxidizing gas in the pod can be effectively suppressed. Further, the present invention can be carried out only by adding the curtain nozzle, the purge nozzle, the port for bottom purge, and the like to existing FIMS systems, and those components can be mounted on standardized systems easily at low cost.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-014069, filed Jan. 29, 2014 which is hereby incorporated by reference herein in its entirety.

What is claimed is:

1. A load port apparatus capable of inserting and removing an object to be contained to and from a pod by removing a lid from the pod so as to open an opening of the pod,
the pod being capable of containing the object to be contained and forming a sealed space by closing the opening with the lid,
the pod comprising at least one pod-side gas feed port, which is formed on a wall surface of the pod and capable of feeding gas from an outside to an inside of the pod,
the load port apparatus comprising:
a mount base configured to allow the pod to be mounted thereon;
a mini-environment configured to accommodate a mechanism for transporting the object to be contained, the mini-environment being arranged adjacently to the mount base;
an opening portion formed in a wall, which is arranged adjacently to the mount base so as to define a part of the mini-environment, the opening portion being arranged so as to be opposed to the opening of the pod mounted on the mount base;
a door configured to cause the inside of the pod and the mini-environment to communicate to each other by opening the opening portion while holding the lid, the door being capable of closing the opening portion while holding the lid;
a feed port configured to feed predetermined gas to the inside of the pod in cooperation with the at least one pod-side gas feed port;
a purge nozzle configured to feed the predetermined gas toward the inside of the pod with the lid opened, the purge nozzle being arranged corresponding to a lateral side of the opening portion on the mini-environment side; and
a control unit configured to determine a period of time for simultaneously feeding the predetermined gas from the purge nozzle and the feed port to the inside of the pod in a state where the lid is removed from the pod by the door.

2. A load port apparatus according to claim 1, wherein the at least one pod-side gas feed port is arranged at a position where the at least one pod-side gas feed port is capable of forming a gas discharge path leading to the outside of the pod along an opposing surface of the opening of the pod for the predetermined gas fed from the purge nozzle to the inside of the pod.

3. A load port apparatus according to claim 1, wherein the control unit comprises:
an opening and closing detection unit configured to detect opening and closing of the opening, which are performed by the door through use of the lid; and
a unit configured to start feed of the predetermined gas from the purge nozzle in accordance with the opening of the opening, which is detected by the opening and closing detection unit.

4. A load port apparatus according to claim 1, wherein the purge nozzle forms a gas flow parallel to a flat mount surface of the mount base.

5. A load port apparatus according to claim 1, wherein the purge nozzle forms a gas flow including a laminar flow, which is parallel to an extending plane of the object to be contained having a plate shape.

6. A load port apparatus according to claim 1,
wherein the pod comprises at least one discharge port, which is formed on the wall surface of the pod and capable of discharging gas to the outside, and
wherein the load port apparatus further comprises a discharge valve configured to discharge the gas from the inside of the pod in cooperation with the at least one discharge port.

7. A load port apparatus according to claim 1, further comprising:
an enclosure being arranged in the mini-environment so as to be continuous from the opening portion and covering a movement space of the door, the enclosure comprising a second opening portion configured to enable the mechanism for transporting the object to be contained to pass through the second opening portion together with the object to be contained while causing the opening portion and the mini-environment to communicate to each other; and
a curtain nozzle configured to form a downflow parallel to the opening portion in the enclosure,
the curtain nozzle and the purge nozzle being arranged in the enclosure.

8. A control method for a load port apparatus capable of inserting and removing an object to be contained to and from a pod by removing a lid from the pod so as to open an opening of the pod,
the pod being capable of containing the object to be contained and forming a sealed space by closing the opening with the lid,
the pod comprising at least one pod-side gas feed port, which is formed on a wall surface of the pod and capable of feeding gas from an outside to an inside of the pod,
the control method comprising:
mounting the pod on a mount base of the load port apparatus;
removing the lid from the pod so that a mini-environment and the inside of the pod communicate to each other through the opening;
feeding predetermined gas from the at least one pod-side gas feed port to the inside of the pod;
feeding the predetermined gas from a purge nozzle arranged in the mini-environment to the inside of the pod; and
closing the opening with the lid,
the feeding the predetermined gas from the purge nozzle to the inside of the pod and the feeding the predetermined gas from the at least one pod-side gas feed port to the inside of the pod being performed simultaneously with each other at least during a period in which the opening is in an opened state.
